(19) United States
(12) Patent Application Publication
(10) Pub. No.: US 2026/0085411 A1
(43) Pub. Date: Mar. 26, 2026

(54) Vapor Delivery System Utilizing Light as a Heating Source for Semiconductor Processing Systems

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/892,510

(22) Filed: Sep. 22, 2024

(51) Int. Cl. C23C 16/448; C23C 16/52; H01L 21/67

(52) U.S. Cl. CPC C23C 16/4481; C23C 16/52; H10P 72/0402; H10P 72/0436; H10P 72/0604

(57) ABSTRACT

Disclosed herein is a liquid precursor delivery system for precise vaporization processes. The system comprises an ampoule, a light-emitting diode heater, a level sensor, and a controller. The level sensor monitors the precursor's surface level, with data processed by the controller to adjust heater power. Optionally, a precursor consumption predictor estimates precursor usage. The design allows dynamic adjustments, enhancing precision in precursor delivery.

### FIELD OF THE INVENTION

The present invention relates to semiconductor processing systems, and more specifically, to systems designed for the delivery of liquid precursors. The invention employs light as the primary heating source to regulate and control the delivery of these precursors during the semiconductor fabrication process.

### BACKGROUND

Semiconductor device fabrication involves a variety of processes requiring the precise delivery of precursors into a process chamber. These precursors, which can exist in gas, liquid, or solid forms, play a critical role in establishing the desired chemical reactions within the chamber. A delivery system that provides precise control over the quantity of precursor introduced into the chamber is essential to maintaining process integrity and efficiency.

### SUMMARY

This summary provides a general overview of certain concepts of the invention. Detailed descriptions of specific embodiments are presented below. This section is not intended to define the essential features or limit the scope of the claimed invention.

In one embodiment, the system comprises a liquid precursor stored in an ampoule, with a light-emitting heating source positioned at a controlled distance from the precursor surface. In another embodiment, a sensor measures the surface level of the liquid precursor, and a controller, receiving input from the sensor, adjusts the power level supplied to the heating source. In some implementations, the heating source consists of an array of light-emitting diodes (LEDs) embedded in a substrate, while in other implementations, the heater may be a lamp or a laser-based system.

The sensor system may utilize ultrasonic distance measurement techniques, or in another embodiment, an optical distance measurement apparatus using time-of-flight (ToF) technology. The surface level of the liquid precursor is monitored at regular intervals during the process step, and changes in the surface level are used to determine the precursor consumption rate. Based on these observations, the controller dynamically adjusts the power supplied to the heating source to ensure that precursor consumption matches the target levels set for the process step.

### BRIEF DESCRIPTION OF THE DRAWINGS

The accompanying drawings illustrate various embodiments of the invention and form part of this specification. These drawings, together with the detailed description, serve to explain the invention's principles and implementations:

FIG. 1A: Schematic representation of an exemplary vapor delivery system featuring a heater and level sensor.

FIG. 1B: Schematic representation of a vapor delivery system with an ultrasonic sensor.

FIG. 1C: Schematic representation of a vapor delivery system utilizing a ToF sensor.

FIG. 1D: Schematic representation of a vapor delivery system with an LED heater array and level sensor.

FIG. 1E: Schematic representation of a vapor delivery system using a lamp as the heating source, with a level sensor.

FIG. 1F: Schematic representation of a vapor delivery system utilizing a laser as the heating mechanism, alongside a level sensor.

FIG. 2: Functional diagram of an exemplary vapor delivery system.

FIG. 3: Illustration of an LED heater array designed for a cylindrical ampoule.

FIG. 4: Diagram detailing a method for adjusting the power supplied to the heater to ensure precursor consumption matches the target by the end of the process step.

FIG. 5: Flowchart of the procedural dynamics of the vapor delivery system, including a level sensor and a precursor consumption predictor.

### DETAILED DESCRIPTION

The following detailed description provides specific illustrative methods to enhance understanding of the invention. However, it will be apparent to those skilled in the art that the invention may be practiced without these particular details or by using alternative elements or processes. In some instances, well-known processes and components have been omitted to avoid obscuring the invention's key aspects.

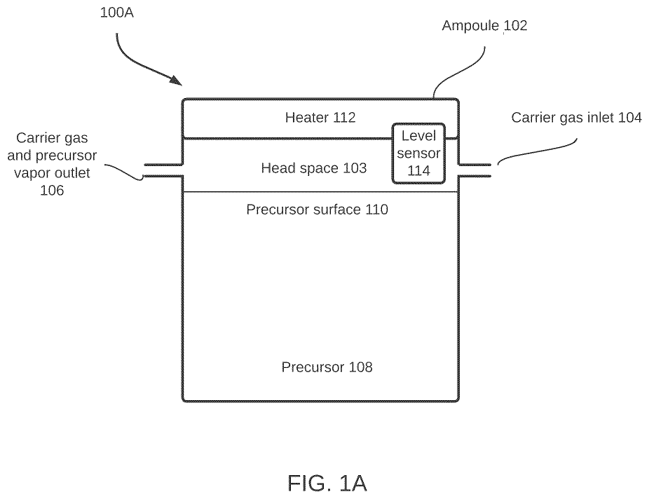

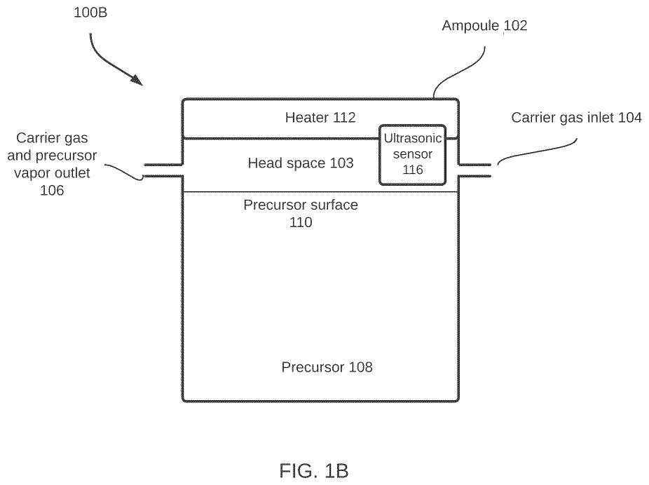

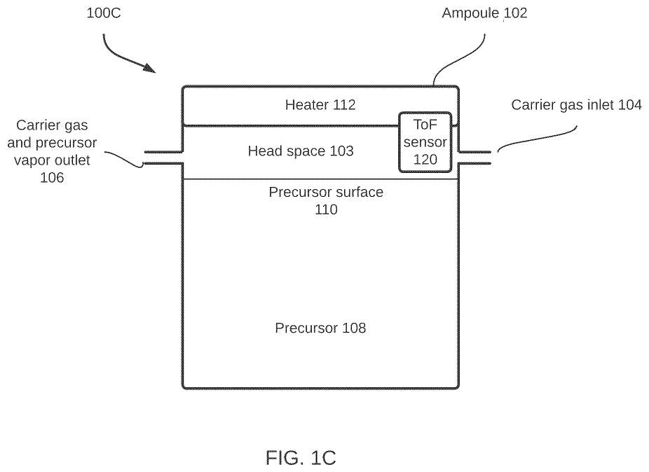

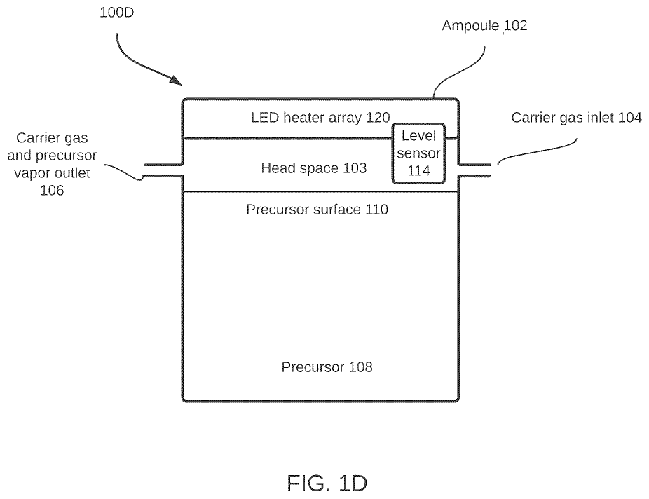

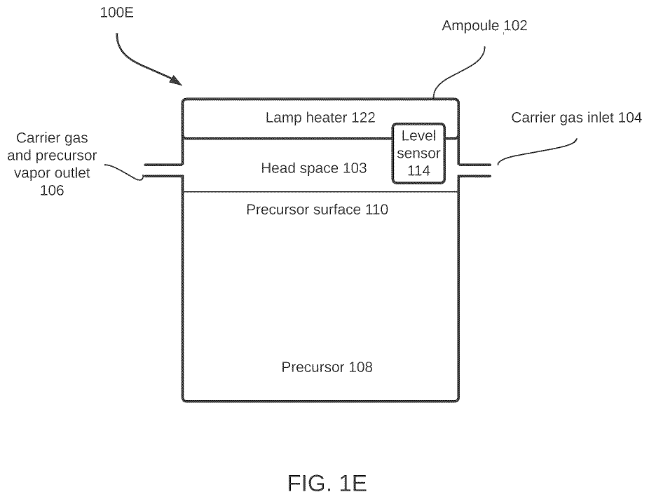

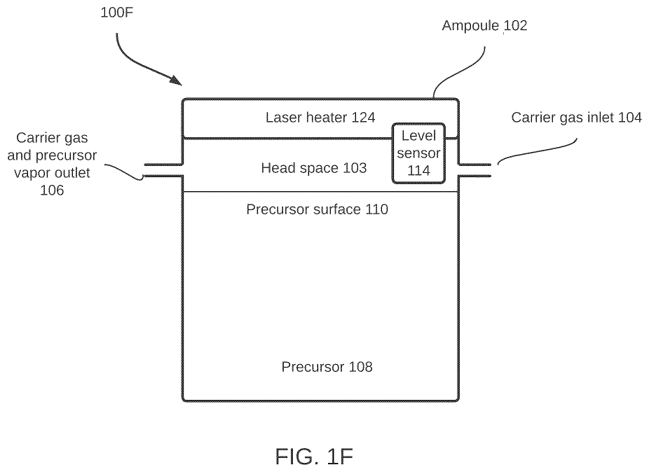

FIG. 1A presents an exemplary vapor delivery system, referred to as 100A. This system includes an ampoule 102 that stores the liquid precursor to be delivered to a process chamber, where it may be used to deposit or remove materials on a substrate. The precursors stored in the ampoule 102 are consumed in the process chamber during chemical or plasma-assisted chemical reactions as part of deposition or etching steps.

The ampoule 102 is a container with an inlet 104 for carrier gas intake. Typically, an inert gas such as argon serves as the carrier. As the carrier gas flows through the headspace 103 of the ampoule, it absorbs and transports the vaporized precursor to the process chamber via the outlet 106. The vaporization of the precursor is primarily achieved by heating it with a heater 112 positioned to raise the precursor's temperature above ambient conditions. Upstream, a mass flow controller (MFC) regulates the carrier gas flow, and some implementations also use a flow sensor downstream of the ampoule 102 to measure the combined flow of carrier gas and precursor vapor. However, such measurements are often imprecise, leading to variability in process results. Conventional heating mechanisms using resistive elements also struggle to maintain a uniform surface temperature and can be slow to respond to adjustments.

The present invention addresses these limitations to deliver consistent and repeatable process outcomes. In one embodiment, illustrated in FIG. 1A, a heater 112 is placed above the precursor surface 110 at a distance of approximately 0.1 to 10 cm. This heater is mounted on a substrate in the upper section of the ampoule 102 and heats the precursor's surface 110 by emitting light. The light energy is absorbed by the liquid molecules, increasing their vibrational energy and raising the temperature. When the temperature reaches the boiling point, the liquid at the surface vaporizes. The absorption of light is optimized by the interaction between the liquid's properties and the wavelength of the emitted light. In certain implementations, the heater emits ultraviolet (UV) light, which has a shallower absorption depth than visible light, concentrating the energy conversion at or near the surface for greater efficiency. This targeted surface heating enables rapid adjustments to the heater's power, allowing dynamic control throughout the process step to ensure precise precursor delivery to the chamber.

System 100A also includes a level sensor 114, shown in FIG. 1A, which measures the surface level of the liquid precursor. Changes in the surface level over time indicate the rate at which the precursor is being consumed. Several methods can be used to monitor the liquid precursor's surface level in ampoule 102.

In one embodiment, shown in FIG. 1B, the level sensor 114 is an ultrasonic sensor 116. The ultrasonic sensor measures distance by emitting sound waves and timing their reflection from the precursor surface 110. The distance is calculated based on the time between emission and reception of the sound waves. In this embodiment, the ultrasonic sensor is positioned above the precursor surface 110. A reference distance is established by measuring from the sensor to the base of the ampoule 102, and changes in the precursor surface level are detected by comparing the time intervals at different points during the process step.

In another embodiment, depicted in FIG. 1C, the level sensor 114 is an optical sensor 118 based on ToF technology. ToF sensors measure distance by calculating the time it takes for a light beam to travel from the sensor to the target (in this case, the precursor surface 110) and back. Like the ultrasonic sensor, the ToF sensor detects changes in the precursor surface level over time by comparing measurements at different intervals.

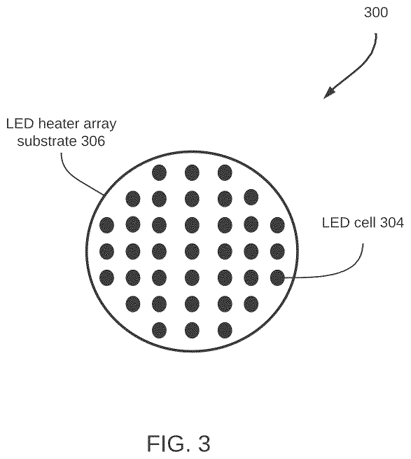

Various heater implementations are possible. FIG. 1D shows an embodiment where the heater 112 is an LED array 120, comprising multiple LEDs positioned above the precursor surface 110 to provide heating. In one implementation, the LED array 120 emits UV light, concentrating energy transfer to the molecules near the surface. An exemplary LED heater array is illustrated in FIG. 3, where an array 302 of LED cells 304 is arranged on a substrate 306. The number of LED cells can range from one to ten thousand. In one embodiment, the ampoule 102 is cylindrical, and the substrate is shaped accordingly, although ampoules of various shapes can be used.

Another heater implementation, shown in FIG. 1E, uses a lamp 122 positioned above the precursor surface 110. In some designs, the lamp emits UV light to transfer photonic energy to the surface molecules.

A further embodiment, shown in FIG. 1F, features a laser heater 124 for heating the precursor surface. The laser 124 may emit UV light in some implementations. Advanced versions of this design may include a scanning feature, allowing the laser beam to traverse the precursor surface systematically to achieve uniform heating. Alternatively, a multi-beam laser configuration could be used for even heating across the precursor surface.

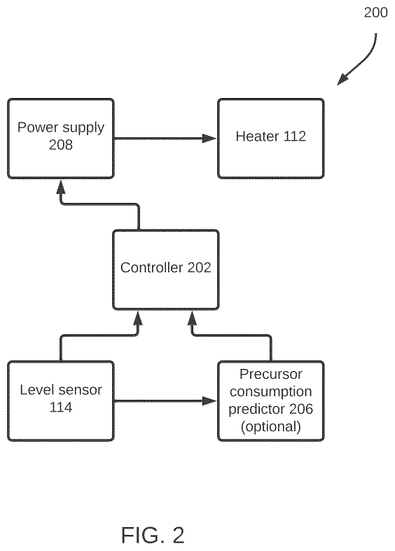

FIG. 2 illustrates a functional diagram of an exemplary vapor delivery system, referred to as 200. This system includes a controller 202. In one embodiment, the controller 202 is a computer responsible for managing the operations of the system 200. The system also includes a previously described level sensor 114, which is monitored by the controller 202. Data collected by the level sensor 114 is transmitted back to the controller.

The system 200 may optionally include a precursor consumption predictor 206. The predictor (206) can be implemented as software, or a combination of software and firmware integrated with the controller 202. The predictor uses data from the level sensor 204 to estimate the precursor consumption during the process step by taking measurements at different time intervals. In one configuration, the predictor 206 calculates precursor consumption based on empirical data, applying a curve-fitting method to the measured data. Alternatively, the predictor may rely on physical or semi-physical models, where the semi-physical models can be calibrated using measured data. In another design, the predictor 206 functions as a neural network, which is trained using either simulation data, real-time measurements, or a combination of both.

A key aspect of this invention is its ability to use the predicted precursor consumption during the process step to adjust the electrical output from the power supply 208 to the LED heater array 210. This improves the likelihood of achieving the desired precursor delivery to the process chamber by the end of the process step. The novel approach of using the heater 210 to emit photons to heat the precursor surface allows for faster surface temperature responses when the power is adjusted. In contrast, traditional methods that use resistive heating for the liquid precursor are slower to adjust the bulk temperature in response to power changes, limiting real-time temperature control.

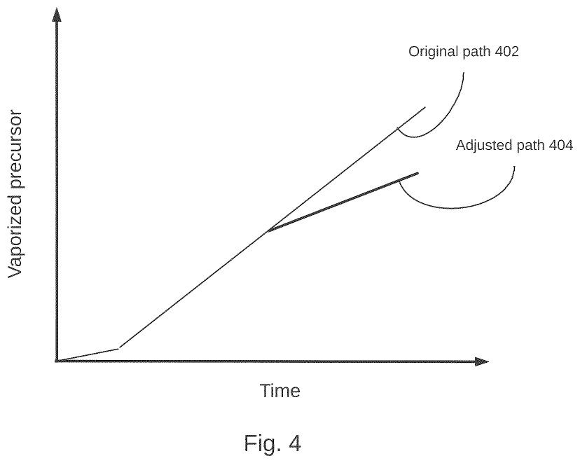

FIG. 4 illustrates a method for adjusting the power supplied to the heater to meet a predetermined precursor consumption target by the end of a process step. In this figure, 402 represents the default precursor consumption path over the course of the process, which, if left unchanged, could result in excessive precursor consumption and a film thickness that is outside the target range. By comparison, 404 shows the adjusted consumption path. For simplicity, the diagram uses a linear consumption model, though real-world applications may require more complex models. Advanced computational tools can handle these more sophisticated models, which could be based on physical or semi-physical principles. In other configurations, a neural network trained on simulated or real data could be used to predict precursor consumption for the remainder of the process step.

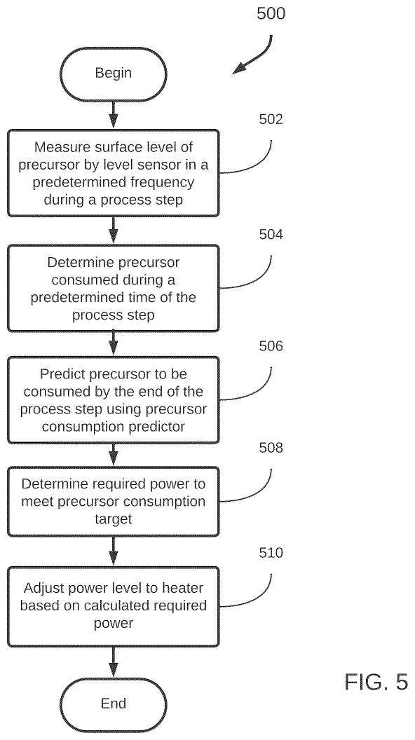

FIG. 5 outlines a flowchart of the process 500 for the vapor delivery system 200, which includes both a level sensor 204 and a precursor consumption predictor 206. In step 502, the surface level of the precursor is measured periodically during the process step, with measurements occurring between one and a thousand times during the step. In step 504, the precursor consumption is calculated up to a certain point in the process. Step 506 involves the predictor 206 projecting the precursor consumption for the remainder of the process step. In step 508, the required power for the LED heater array (210) is determined for the remaining portion of the process step. Finally, in step 510, the power level supplied from the power supply 208 to the LED heater array 210 is adjusted based on the power requirement identified in the previous step.

1. A vapor delivery system, comprising:
an ampoule for containing a liquid precursor, equipped with an inlet for introducing a carrier gas and an outlet for discharging the carrier gas combined with vaporized precursor;
a heater designed to increase the temperature of the liquid precursor surface by projecting light onto it;
a level sensor configured to measure the surface level of the liquid precursor; and
a controller configured to receive data from the level sensor and adjust the power level supplied to the heater.

2. The system as claimed in claim 1, wherein the level sensor comprises an ultrasonic sensor.

3. The system as claimed in claim 1, wherein the level sensor comprises an optical sensor operating on time-of-flight (ToF) principles.

4. The system as claimed in claim 1, wherein the heater comprises a light-emitting diode (LED) heater array.

5. The system as claimed in claim 4, wherein the LED heater array comprises ultraviolet light-emitting diodes.

6. The system as claimed in claim 1, wherein the heater comprises a lamp.

7. The system as claimed in claim 6, wherein the lamp emits ultraviolet light.

8. The system as claimed in claim 1, wherein the heater comprises a laser.

9. The system as claimed in claim 8, wherein the laser includes a scanning mechanism to ensure uniform heating of the liquid precursor surface.

10. The system as claimed in claim 8, wherein the laser includes a multi-beam configuration to ensure uniform heating across the liquid precursor surface.

11. The system as claimed in claim 1, wherein the controller further includes a liquid precursor consumption predictor designed to estimate precursor usage by the end of a process step, based on changes in the surface level detected by the level sensor during the process step.

12. A method for precisely transferring a liquid precursor from an ampoule to a process chamber, comprising:
determining, by a controller, a targeted surface level reduction for a liquid precursor stored in the ampoule during a process step;
determining, by the controller, the initial power supplied to a heater; and
adjusting, by the controller, the power level supplied to the heater based on surface level changes measured by the level sensor during the process step.

13. The method as claimed in claim 12, further comprising predicting the surface level change by the end of the process step by a precursor consumption predictor, based on surface level changes observed during the process step.

14. The method as claimed in claim 13, further comprising calculating the difference between the predicted and desired surface level changes by the end of the process step by the precursor consumption predictor.

15. The method as claimed in claim 13, wherein the precursor consumption predictor further includes a model implemented as a software.

16. A process system, comprising:
a vapor delivery system, including:
a heater positioned above the liquid precursor surface within an ampoule; and a controller configured to monitor and model surface level changes during and by the end of a process step using a level sensor and software, respectively, wherein the controller adjusts the power level supplied to the heater to minimize the difference between targeted and actual precursor consumption by the end of the process step;
a process chamber configured for vacuum-based processing; and
a precursor delivery unit for distributing the precursor into the process chamber.

17. The system as claimed in claim 16, wherein the process chamber is used for a plasma-enhanced chemical vapor deposition (PECVD) process.

18. The system as claimed in claim 16, wherein the process chamber is used for an atomic layer deposition (ALD) process.

19. The system as claimed in claim 16, wherein the process chamber is used for both etching and deposition processes.

20. The system as claimed in claim 1, wherein the controller models precursor consumption using a neural network.
